(19) United States
(12) Patent Application Publication
(10) Pub. No.: US 2005/0087139 A1
(43) Pub. Date: Apr. 28, 2005

(54) Antenna for use in producing plasma and plasma processing apparatus comprising the same

(76) Inventors: Woo-Seok Kim, Suwon-si (KR); Seung-Ki Chae, Seoul (KR); Do-Young Kam, Suwon-si (KR); Kwang-Myung Lee, Suwon-si (KR); Jai-Hyung Won, Sungnam-si (KR); Jai-Kwang Shin, Anyang-si (KR); Jae-Joon Oh, Sungnam-si (KR); Sang-Jean Jeon, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/969,928

(22) Filed: Oct. 22, 2004

(30) Foreign Application Priority Data
Oct. 28, 2003 (KR) 2003-75435

(51) Int. Cl. C23C 16/00

(52) U.S. Cl. 118/723 AN

(57) ABSTRACT

An antenna includes branches having substantially identical shapes. The branches are symmetrically disposed about a central point and extend along at least two concentric patterns whose geometric centers coincide with the central point. The branches each include pattern-forming portions that lie entirely within the concentric patterns, and at least one connecting portion extending between and connecting the pattern-forming portions. Input/output terminals for allowing a voltage to be impressed across the branches are provided at ends of each of the branches.

### BACKGROUND OF THE INVENTION

1. Field of the Invention

The present invention relates to plasma processing apparatus used in the manufacturing of semiconductor devices and the like. More particularly, the present invention relates to an antenna for generating plasma in plasma processing apparatus.

2. Description of the Related Art

Generally, a deposition process and an etching process are performed on a semiconductor substrate to form a minute circuit pattern or feature of a semiconductor device. A commonly used piece of equipment for performing the deposition and etching processes is a plasma processing apparatus.

Plasma processing apparatus may classified—in accordance with the methods that the apparatus employ to generate plasma—as inductively coupled plasma processing apparatus, capacitively coupled plasma processing apparatus and microwave plasma processing apparatus. Capacitively coupled plasma processing apparatus have a simple structure, and generate uniform plasma. Capacitively coupled plasma processing apparatus require a long time to carry out a deposition process because they produce plasma having a low density. On the other hand, inductively coupled plasma processing apparatus can perform a deposition process in a short amount of time because they can produce plasma having a high density. However, and despite being widely used, the inductively coupled plasma processing apparatus generate non-uniform plasma.

More specifically, an inductively coupled plasma processing apparatus includes a chamber in which plasma is generated. The chamber has a gas inlet through which a reaction gas is supplied into the chamber, a vacuum pump for creating a vacuum in the chamber, and a gas outlet through which gas is discharged from the chamber. A chuck on which a wafer is supported is disposed at a lower portion of the chamber. An antenna is disposed at an upper portion in the chamber. Plasma is generated in the chamber by applying a voltage to the reaction gas using the antenna.

The antenna may be a single-branch type or a multi-branch type of antenna. Although impedance is easily matched in the single-branch type of antenna, the single-branch type outputs radio frequency (RF) power with a low degree of efficiency due to its high impedance. On the other hand, the multi-branch type of antenna is highly efficient at producing RF power due to its low impedance and the azimuthal uniformity it provides. However, in the multi-branch type of antenna, the current may not be uniformly distributed to the branches that are disposed in parallel.

FIG. 14 shows another type of conventional antenna for generating plasma. This antenna includes a spiral branch, and input/output terminals provided on both ends of the spiral branch, respectively. Because the branch is spiral, the radius of curvature of the branch varies over the length of the branch. In other words, the distance between the geometric center of the branch and the branch itself changes in accordance with the relative angular position of the branch.

The pattern of the electric field generated by the conventional antenna corresponds to the spiral shape of the branch. As a result, the distribution of the plasma produced using the conventional antenna is biased towards one side of the chamber. That is, the conventional antenna can not be used to produce a uniform plasma.

Furthermore, the conventional antenna is electrically connected in series. Therefore, the conventional antenna is characterized as having a high impedance. Thus, the conventional antenna transmits an RF power with a low degree of efficiency.

### SUMMARY OF THE INVENTION

An object of the present invention is to provide an antenna that facilitates the production of uniform plasma and also has low impedance.

Likewise, an object of the present invention is to provide a plasma processing apparatus that produces uniform plasma and comprises an antenna that has low impedance.

In accordance with one aspect of the present invention, an antenna includes discrete branches having substantially identical shapes. The branches are symmetrically disposed and lie along at least two geometric figures that are concentric with respect to a central axis about which the branches are symmetrically disposed.

The branches may extend along concentric circles. In this case, each of the branches includes a plurality of arcuate pattern-forming portions, and at least one connecting portion extending between and connecting the pattern-forming portions. The pattern-forming portions constituting each of the branches have different radii of curvature.

In accordance with another aspect of the present invention, a plasma processing apparatus includes a chamber into which a reaction gas is introduced, a chuck on which a wafer is to be supported disposed at a lower portion of the chamber, and an antenna having the aforementioned characteristics disposed over the chamber. Input/output terminals for impressing a voltage across the branches are provided at both ends of the branches.

The upper wall of the chamber may substantially be flat. In this case, the pattern-forming portions of the branches of the antenna all lie in substantially the same plane. Alternatively, the upper wall of the chamber may be dome-shaped. In this case, the pattern-forming portions constituting each of said branches are disposed in parallel planes, respectively, spaced along the height of said dome-shaped upper wall.

According to the present invention, a uniform plasma can be produced because the branches of the antenna basically form a pattern of concentric geometric figures such as circles. Also, the branches are electrically connected in parallel so that the antenna has low impedance and can thus transmit power to the reaction gas with a high degree of efficiency.

### BRIEF DESCRIPTION OF THE DRAWINGS

The above and other objects, features and advantages of the present invention will become more apparent from the following detailed description of the preferred embodiments thereof made with reference to the attached drawings, in which:

FIG. 1 is a plan view of a first embodiment of an antenna in accordance with the present invention;

FIG. 2 is a plan view of a second embodiment of an antenna in accordance with the present invention;

FIG. 3 is a plan view of a third embodiment of an antenna in accordance with the present invention;

FIG. 4 is a plan view of a fourth embodiment of an antenna in accordance with the present invention;

FIG. 5 is a plan view of a fifth embodiment of an antenna in accordance with the present invention;

FIG. 6 is a plan view of a sixth embodiment of an antenna in accordance with the present invention;

FIG. 7 is a plan view of a seventh embodiment of an antenna in accordance with the present invention;

FIG. 8 is a plan view of eighth embodiment of an antenna in accordance with the present invention;

FIG. 9 is a plan view of a ninth embodiment of an antenna in accordance with the present invention;

FIG. 10 is a plan view of a tenth embodiment of an antenna in accordance with the present invention;

FIG. 11 is a plan view of an eleventh embodiment of an antenna in accordance with the present invention;

FIG. 12 is a cross-sectional view of a plasma processing apparatus having the antenna shown in FIG. 1 in accordance with the present invention;

FIG. 13 is a cross-sectional view of a plasma processing apparatus having the antenna shown in FIG. 10 in accordance with the present invention;

FIG. 14 is a perspective view of a conventional antenna;

FIG. 15 is a perspective view of the antenna shown in FIG. 5 in accordance with the present invention;

FIG. 16 is an image of a magnetic field generated by current flowing through the conventional antenna shown in FIG. 14;

FIG. 17 is an image of a magnetic field generated by current flowing through the antenna shown in FIG. 15;

FIG. 18 is an image of an electric field generated by the conventional antenna shown in FIG. 14; and

FIG. 19 is an image of an electric field generated by the antenna shown in FIG. 15.

### DETAILED DESCRIPTION OF THE PREFERRED EMBODIMENTS

### Embodiment 1

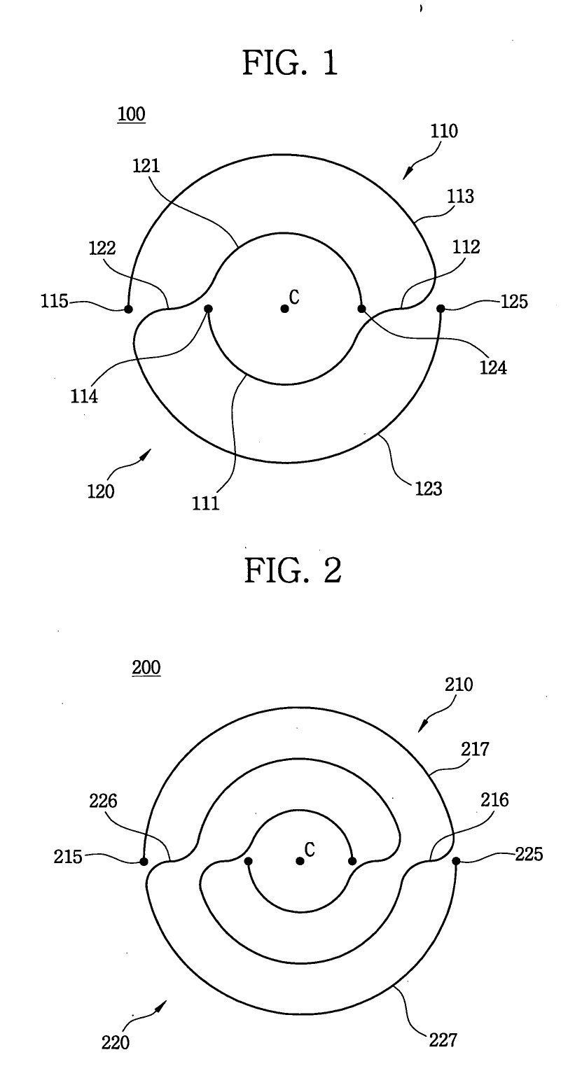

Referring to FIG. 1, a first embodiment of an antenna 100 in accordance the present invention includes first and second branches 110 and 120 having substantially identical shapes. The first and second branches 110 and 120 comprise conductive material and also are in the form of wire. Moreover, the first and second branches 110 and 120 are symmetrically disposed about a central axis passing through center C and lie along two concentric circles whose centers coincide with center C.

More specifically, the first and second branches 110 and 120 include first semicircular pattern-forming portions 111 and 121, second semicircular pattern-forming portions 113 and 123 each having a radius greater than those of the first pattern-forming portions 111 and 121, and connecting portions 112 and 122 extending between adjacent ends of the first pattern-forming portions 111 and 121 and the second pattern-forming portions 113 and 123, respectively. The first pattern-forming portions 111 and 121 and the second pattern-forming portions 113 and 123 lie in substantially the same plane.

The first pattern-forming portion 111 of the first branch 110 and the first pattern-forming portion 121 of the second branch 120 extend along a first circle having the center C. The second pattern-forming portion 113 of the first branch 110 and the second pattern-forming portion 123 of the second branch 120 extend along a second circle having a diameter greater than that of the first circle. The interval between the first pattern-forming portions 111 and 121 and the second pattern-forming portions 113 and 123, i.e., the spacing between the first pattern-forming portions 111 and 121 and the second pattern-forming portions 113 and 123 in the radial direction from center C, is substantially constant.

Also, the ends of the first and second branches 110 and 120 are located along a central line that passes through the center C. Input/output terminals 114, 115, 124 and 125 are provided at the ends of the first and second branches 110 and 120. The input/output terminals 114, 115, 124 and 125 are used for impressing a voltage across the first and second branches 110 and 120. Accordingly, when the terminals 114 and 124 closest to the center C are the input terminals for the first and second branches 110 and 120, the terminals 115 and 125 are the output terminals for grounding the first and second branches 110 and 120. On the other hand, when the terminals 114 and 124 closest to the center C are the output terminals for grounding the first and second branches 110 and 120, the terminals 115 and 125 are the input terminals.

### Embodiment 2

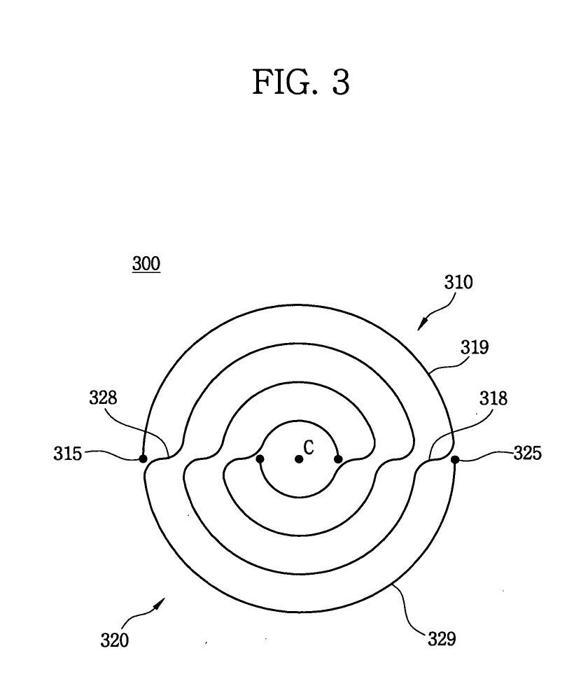

Referring to FIG. 2, another antenna 200 in accordance with the present invention includes first and second branches 210 and 220 having substantially identical shapes. The first and second branches 210 and 220 form three concentric circles lying in substantially the same plane. The first and second branches 210 and 220 include third pattern-forming portions 217 and 227 connected to first and second branches, similar to the first and second branches 110 and 120 shown in FIG. 1, via connecting portions 216 and 226. The third pattern-forming portions 217 and 227 extend along a third circle having a diameter greater than that of the second circle. The spacing between each adjacent pair of the concentric circles is the same. Terminals 215 and 225 are provided at outer ends of the third pattern-forming portions 217 and 227.

### Embodiment 3

Referring to FIG. 3, another antenna 300 in accordance with the present invention includes first and second branches 310 and 320 having substantially identical shapes. The first and second branches 310 and 320 form four concentric circles in substantially the same plane. The first and second branches 310 and 320 include fourth pattern-forming portions 319 and 329 connected to first, second and third branches, similar to those shown in FIG. 2, via connecting portions 318 and 328. The fourth pattern-forming portions 319 and 329 extend along the fourth (outermost) one of the concentric circles. The intervals between the concentric circles are substantially identical. Terminals 315 and 325 are provided at outer ends of the fourth concentric pattern-forming portions 319 and 329.

Also, an antenna according to the present invention may have five or more pairs of pattern-forming portions wherein each pair extends along a respective one of concentric circles, in accordance with the principles of the first to third embodiments.

### Embodiment 4

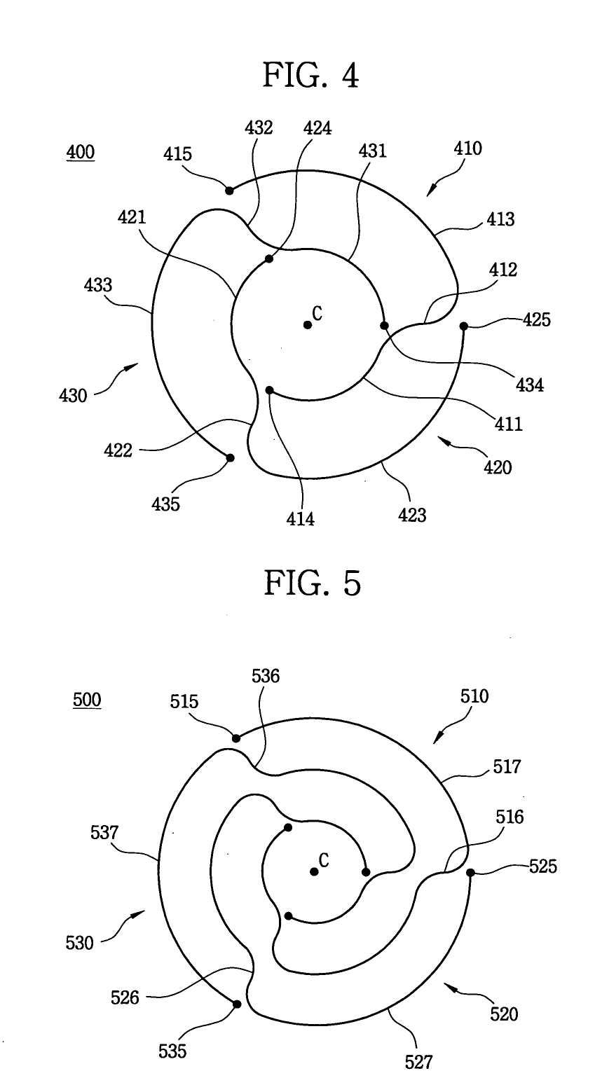

Referring to FIG. 4, another antenna 400 in accordance with the present invention includes first, second and third branches 410, 420 and 430 having substantially identical shapes. The first, second and third branches 410, 420 and 430 are symmetrically disposed about a center C and form two concentric circles having center C.

The first, second and third branches 410, 420 and 430 include first pattern-forming portions 411, 421 and 431 each having the shape of one third of a circle, second pattern-forming portions 413, 423 and 433 each having the shape of one third of a larger circle, and connecting portions 412, 422 and 432 extending between adjacent ends of the first pattern-forming portions 411, 421 and 431 and second pattern-forming portions 413, 423 and 433. The first, second and third branches 410, 420 and 430 lie in substantially the same plane.

More specifically, the first pattern-forming portion 411 of the first branch 410, the first pattern-forming portion 421 of the second branch 420, and the first pattern-forming portion 431 of the third branch 430 extend along a first circle. The second pattern-forming portion 413 of the first branch 410, the second pattern-forming portion 423 of the second branch 420, and the second pattern-forming portion 433 of the third branch 430 extend along a second circle having a diameter greater than that of the first circle. The distance, i.e., spacing in the radial direction, between the first pattern-forming portions 411, 421 and 431 and second pattern-forming portions 413, 423 and 433 is constant. Thus, the first and second circles are concentric about center C.

Each of the ends of the first, second and third branches 410, 420 and 430 lie along one of three lines that extended radially outwardly from the center C. The three lines subtend angles of about 120°. Input/output terminals 414, 415, 424, 425, 434 and 435 are provided at the ends of the first, second and third branches 410, 420 and 430. The input/output terminals 414, 415, 424, 425, 434 and 435 are used for impressing a voltage across the first, second and third branches 410, 420 and 430. Accordingly, when the terminals 414, 424 and 434 closest to the center C are used as the input terminals for the first, second and third branches 410, 420 and 430, the terminals 415, 425 and 435 are used as the output terminals for grounding the first, second and third branches 410, 420 and 430. On the other hand, when the terminals 414, 424 and 434 closest to the center C are used as the output terminals for grounding the first, second and third branches 410, 420 and 430, the terminals 415, 425 and 435 are used as the input terminals for the first, second and third branches 410, 420 and 430.

### Embodiment 5

Referring to FIG. 5, another antenna 500 in accordance with the present invention includes first, second and third branches 510, 520 and 530 having substantially identical shapes. The first, second and third branches 510, 520 and 530 extend along three concentric circles lying in substantially the same plane. The first, second and third branches 510, 520 and 530 include third pattern-forming portions 517, 527 and 537 connected to first and second pattern-forming portions, similar to the first pattern-forming portions 411, 421 and 431 and second pattern-forming portions 413, 423 and 433 shown in FIG. 4, via connecting portions 516, 526 and 536, respectively. The third pattern-forming portions 517, 527 and 537 extend along a third circle having a diameter greater than that of the second circle along which the second pattern-forming portions extend. The intervals between the concentric circles are substantially identical. Terminals 515, 525 and 535 are provided at outer ends of the third pattern-forming portions 517, 527 and 537, respectively.

### Embodiment 6

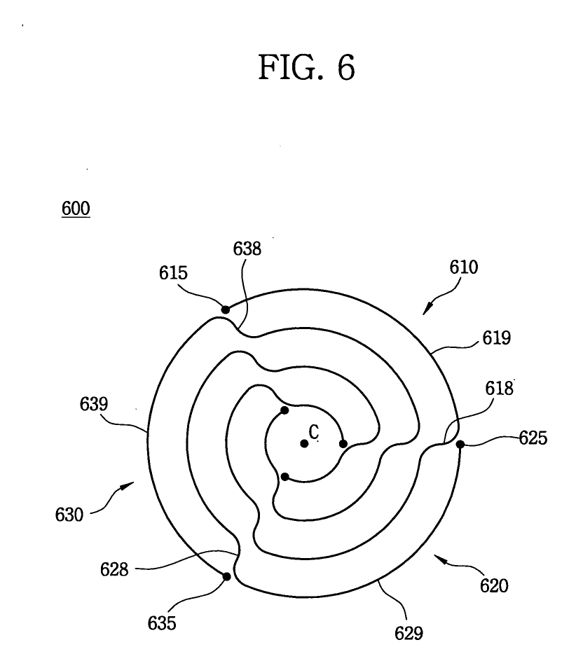

Referring to FIG. 6, another antenna 600 in accordance with the present invention includes first, second and third branches 610, 620 and 630 having substantially identical shapes. The first, second and third branches 610, 620 and 630 extend along four concentric circles lying in substantially the same plane. The first, second and third branches 610, 620 and 630 include fourth pattern-forming portions 617, 627 and 637 connected to first, second and third pattern-forming portions, similar to those shown in FIG. 5, via connecting portions 616, 626 and 636, respectively. The fourth pattern-forming portions 617, 627 and 637 extend along a fourth circle having a diameter greater than that of the third circle along which the third pattern-forming portions extend. The intervals between the concentric circles are substantially identical. Terminals 615, 625 and 635 are provided at outer ends of the fourth pattern-forming portions 617, 627 and 637, respectively.

Also, an antenna according to the present invention may have five or more sets of three pattern-forming portions wherein each set extends along a respective one of concentric circles, in accordance with the principles of the fourth to sixth embodiments.

### Embodiment 7

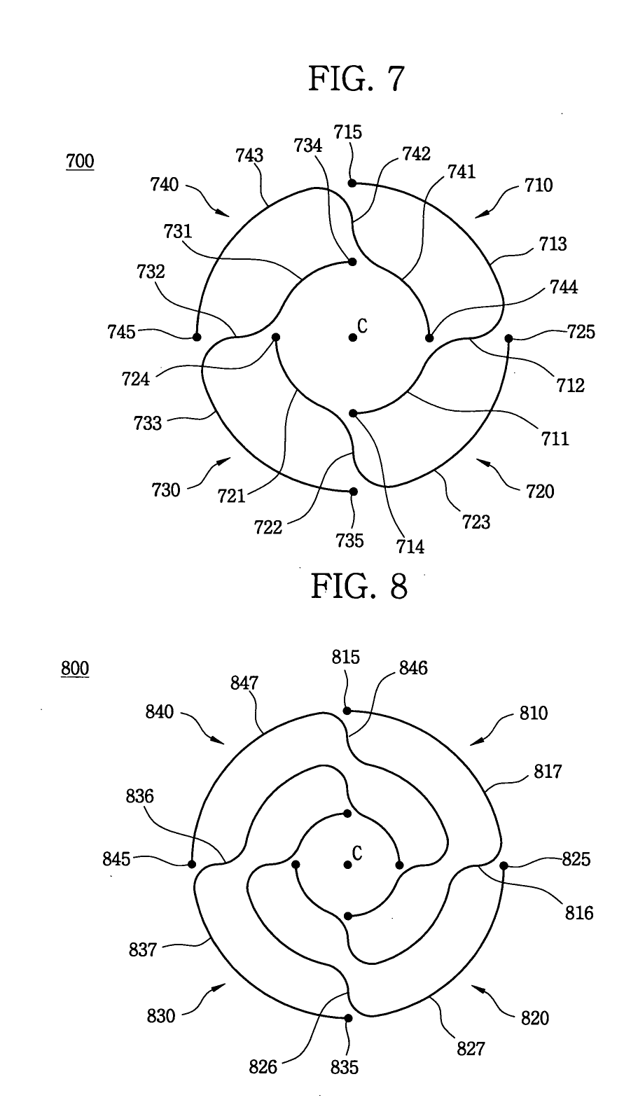

Referring to FIG. 7, another antenna 700 in accordance with the present invention includes first, second, third and fourth branches 710, 720, 730 and 740 having substantially identical shapes. The first, second, third and fourth branches 710, 720, 730 and 740 are symmetrically disposed about a center C and lie along two concentric circles having the center C.

The first, second, third and fourth branches 710, 720, 730 and 740 include first pattern-forming portions 711, 721, 731 and 741 each having the shape of one quarter of a circle, second pattern-forming portions 713, 723, 733 and 743 each having the shape of one quarter of a larger circle, and connecting portions 712, 722, 732 and 742 extending between respective ends of the first pattern-forming portions 711, 721, 731 and 741 and second pattern-forming portions 713, 723, 733 and 743. The first, second, third and fourth branches 710, 720, 730 and 740 lie in substantially the same plane.

The first pattern-forming portion 711 of the first branch 710, the first pattern-forming portion 721 of the second branch 720, the first pattern-forming portion 731 of the third branch 730 and the first pattern-forming portion 741 of the fourth branch 740 lie along a first circle. The second pattern-forming portion 713 of the first branch 710, the second pattern-forming portion 723 of the second branch 720, the second pattern-forming portion 733 of the third branch 730 and the second pattern-forming portion 743 of the fourth branch 740 lie along a second circle having a diameter greater than that of the first circle. The distance, i.e., radial spacing, between the first pattern-forming portions 711, 721, 731 and 741 and second pattern-forming portions 713, 723, 733 and 743 is substantially constant. Thus, the first and second circles are concentric about center C.

Each of the ends of the first, second, third and fourth branches 710, 720, 730 and 740 lies along a respective one of four lines extending radially outwardly from the center C. The lines subtend angles of about 900. Input/output terminals 714, 715, 724, 725, 734, 735, 744 and 745 are provided at ends of the first, second, third and fourth branches 710, 720, 730 and 740, respectively. The input/output terminals 714, 715, 724, 725, 734, 735, 744 and 745 are used for impressing a voltage across the first, second, third and fourth branches 710, 720, 730 and 740. Accordingly, when the ports 714, 724, 734 and 744 closest to the center C are used as the input terminals for the first, second, third and fourth branches 710, 720, 730 and 740, the terminals 715, 725, 735 and 745 are used as output terminals for grounding the first, second, third and fourth branches 710, 720, 730 and 740. On the other hand, when the terminals 714, 724, 734 and 744 closest to the center C are used as output terminals for grounding the first, second, third and fourth branches 710, 720, 730 and 740, the terminals 715, 725, 735 and 745 are used as the input terminals for the first, second, third and fourth branches 710, 720, 730 and 740.

### Embodiment 8

Referring to FIG. 8, another antenna 800 in accordance with the present invention includes first, second, third and fourth branches 810, 820, 830 and 840 having substantially identical shapes. The first, second, third and fourth branches 810, 820, 830 and 840 extend along three concentric circles lying in substantially the same plane. The first, second, third and fourth branches 810, 820, 830 and 840 include third pattern-forming portions 817, 827, 837 and 847 connected to first and second pattern-forming portions, similar to the first pattern-forming portions 711, 721, 731 and 741 and second pattern-forming portions 713, 723, 733 and 743 shown in FIG. 7, via connecting portions 816, 826, 836 and 846. The third pattern-forming portions 817, 827, 837 and 847 extend along a third circle having a diameter greater than that of the second circle along which the second pattern-forming portions extend. The intervals between the concentric circles are substantially identical. Terminals 815, 825, 835 and 845 are provided at outer ends of the third pattern-forming portions 817, 827, 837 and 847, respectively.

### Embodiment 9

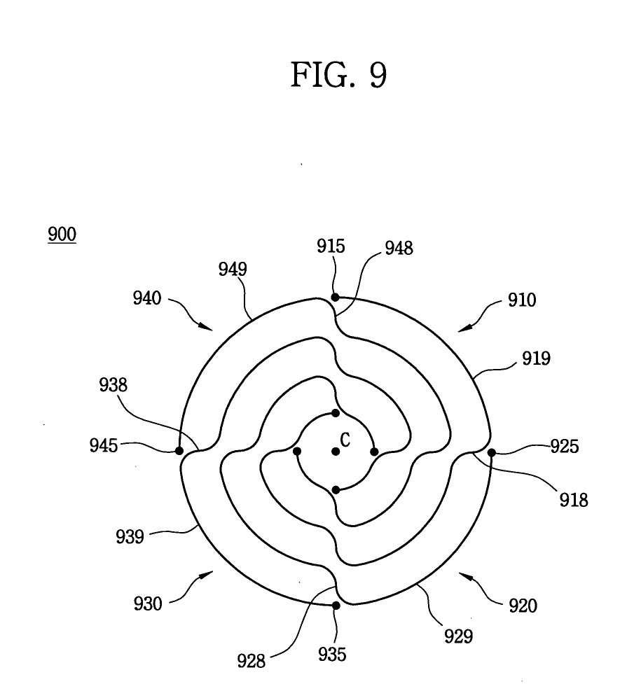

Referring to FIG. 9, another antenna 900 in accordance with the present invention includes first, second, third and fourth branches 910, 920, 930 and 940 having substantially identical shapes. The first, second, third and fourth branches 910, 920, 930 and 940 extend along four concentric circles lying in substantially the same plane. The first, second, third and fourth branches 910, 920, 930 and 940 include fourth pattern-forming portions 917, 927, 937 and 947 connected to the first, second, third and pattern-forming portions, similar to those shown in FIG. 8, via connecting portions 916, 926, 936 and 946. The fourth pattern-forming portions 917, 927, 937 and 947 extend along a fourth circle having a diameter greater than that of the third circle along which the third pattern-forming portions extend. The intervals between the concentric circles are substantially identical. Terminals 915, 925, 935 and 945 are provided at outer ends of the fourth pattern-forming portions 917, 927, 937 and 947 respectively.

Also, an antenna according to the present invention may have five or more sets of four pattern-forming portions wherein each set extends along a respective one of concentric circles, in accordance with the principles of the seventh to ninth embodiments.

### Embodiment 10

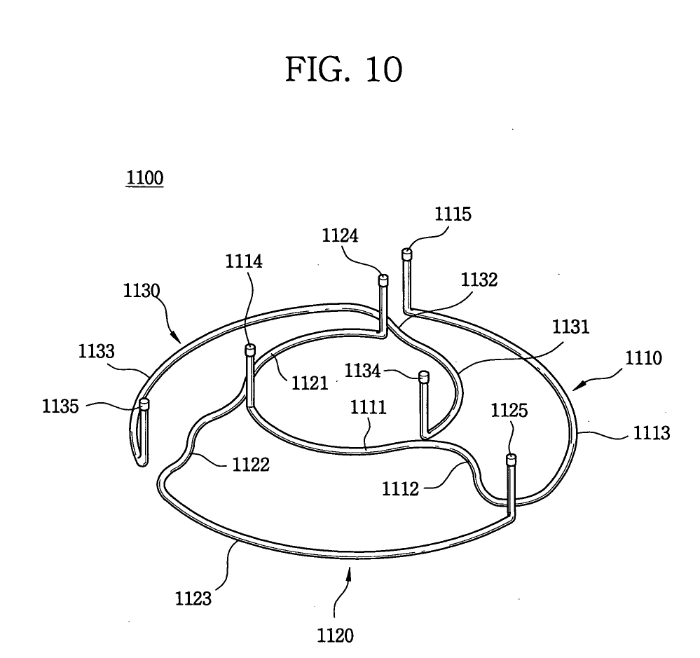

Referring to FIG. 10, another antenna 1100 in accordance with the present invention includes first, second and third branches 1110, 1120 and 1130 having substantially identical shapes. The first, second and third branches 1110, 1120 and 1130 are symmetrically disposed about a central axis passing through center C and lie along two concentric circles whose centers coincide with the central axis.

The first, second and third branches 1110, 1120 and 1130 include first pattern-forming portions 1111, 1121 and 1131 each having the shape of one third of a circle, second pattern-forming portions 1113, 1123 and 1133 each having the shape of one third of a large circle, and connecting portions 1112, 1122 and 1132 extending between ends of the first pattern-forming portions 1111, 1121 and 1131 and second pattern-forming portions 1113, 1123 and 1133. The first pattern-forming portions 1111, 1121 and 1131 lie along a first plane and the second pattern-forming portions 1113, 1123 and 1133 lie along a second plane spaced vertically from the first plane.

Input/output terminals 1114, 1115, 1124, 1125, 1134 and 1135 are provided at the ends of the first, second and third branches 1110, 1120 and 1130. The input/output terminals 1114, 1115, 1124, 1125, 1134 and 1135 are used for impressing a voltage across the first, second and third branches 1110, 1120 and 1130. Accordingly, when the terminals 1114, 1124 and 1134 closest to the center C are used as the input terminals for the first, second and third branches 1110, 1120 and 1130, the terminals 1115, 1125 and 1135 are used as the output terminals for grounding the first, second and third branches 1110, 1120 and 1130. On the other hand, when the terminals 1114, 1124 and 1134 closest to the center C are used as the output terminals for grounding the first, second and third branches 1110, 1120 and 1130, the terminals 1115, 1125 and 1135 are used as the input terminals for the first, second and third branches 1110, 1120 and 1130.

In the present embodiment, the antenna 1100 has the three branches 1110, 1120 and 1130 comprising pattern-forming portions each having the shape of one third of a circle. However, an antenna according to the present invention may have other numbers of branches comprising pattern-forming portions that are each semi-circular or have the shape of a quarter of a circle.

### Embodiment 11

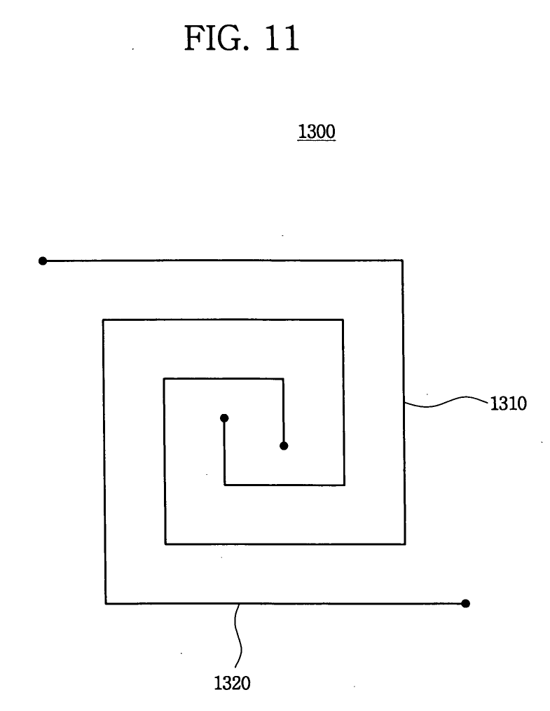

Referring to FIG. 11, an antenna 1300 in accordance with the present invention includes first and second branches 1310 and 1320 having substantially identical shapes. The first and second branches 1310 and 1320 are bent at angles of about 90°. The first and second branches 1310 and 1320 are symmetrically disposed about a central point, and extend along a series of rectangles each having a center at that point.

The branches of the embodiments of the antennas described above are electrically connected to a high frequency power source. Accordingly, current flows in parallel along the branches, thereby reducing impedance of the antennas. As a result, can transmit an RF power to plasma with a high degree of efficiency. Furthermore, the branches are symmetrically disposed so that the plasma generated using the antennas is uniform.

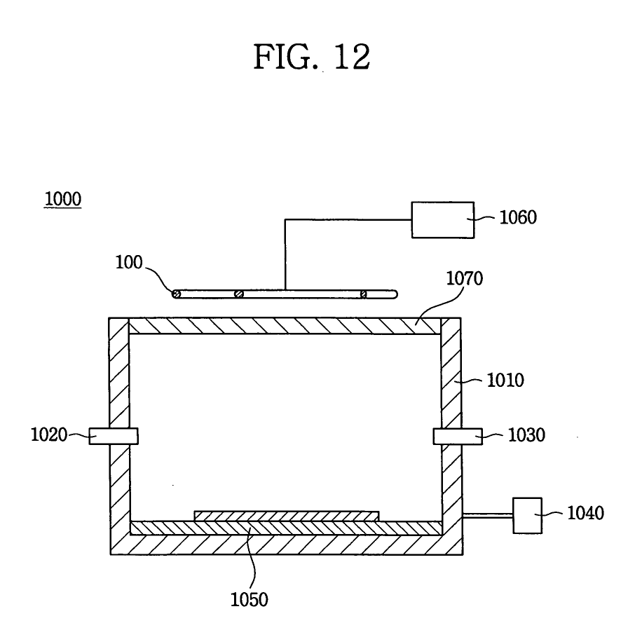

FIG. 12 illustrates a plasma processing apparatus 1000 having an antenna 100 in accordance with the embodiment of FIG. 1. Referring to FIG. 12, the plasma processing apparatus 1000 also includes a chamber 1010 in which a plasma process is performed, a gas inlet 1120 through which reaction gas is introduced into the chamber 1010, and a gas outlet 1130 through which gas generated as the result of a reaction in the chamber 1010 is discharged from the chamber 1010. A vacuum pump 1040 for creating a vacuum in the chamber 1010 is connected to the chamber 1010. The chamber 1010 is cylindrical shape and has also a flat upper wall 1070.

A chuck 1050 on which a wafer is supported is disposed at a lower portion of the chamber 1010. The antenna 100 is disposed over the chamber 1010. Alternatively, other embodiments of the antennas according to the present invention may be employed in the plasma processing apparatus 1000. A power source 1060 outputting a high frequency power is connected to the antenna 100.

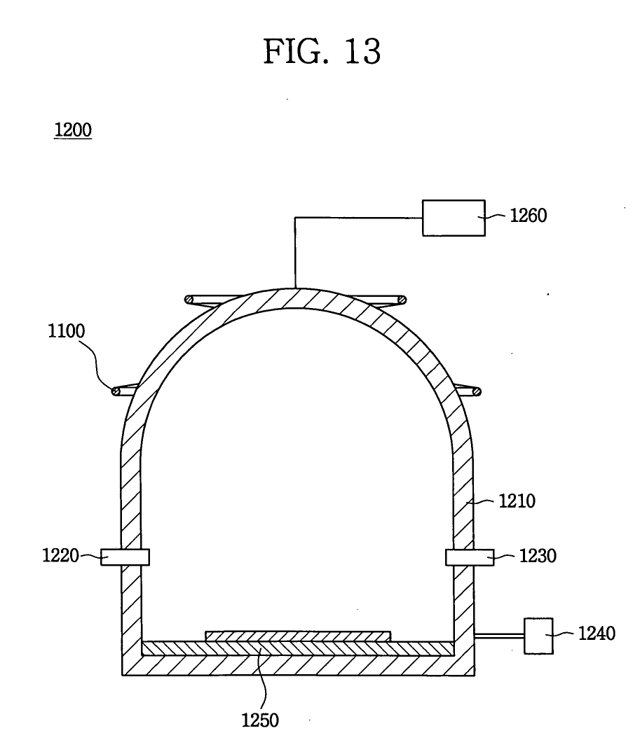

FIG. 13 illustrates a plasma processing apparatus 1200 having an antenna 1100 in accordance with the embodiment of FIG. 10. Referring to FIG. 13, the plasma processing apparatus 1200 also includes a chamber 1210 having an upper wall in the form of a dome. A gas inlet 1220 and a gas outlet 1230 communicate with the interior of the chamber 1210. A vacuum pump 1240 for creating a vacuum in the chamber 1210 is connected to the chamber 1210. A chuck 1250 on which a wafer is supported is disposed at a lower portion of the chamber 1210. A power source 1260 outputting a high frequency power is connected to the antenna 1100. The antenna 1100 surrounds the upper portion of the chamber 1210, i.e., the dome, because the pattern-forming portions of the antenna are disposed along respective planes as described in connection with FIG. 10.

Measurements of Magnetic Fields Generated by a Conventional Antenna and by an Antenna According to the Present Invention

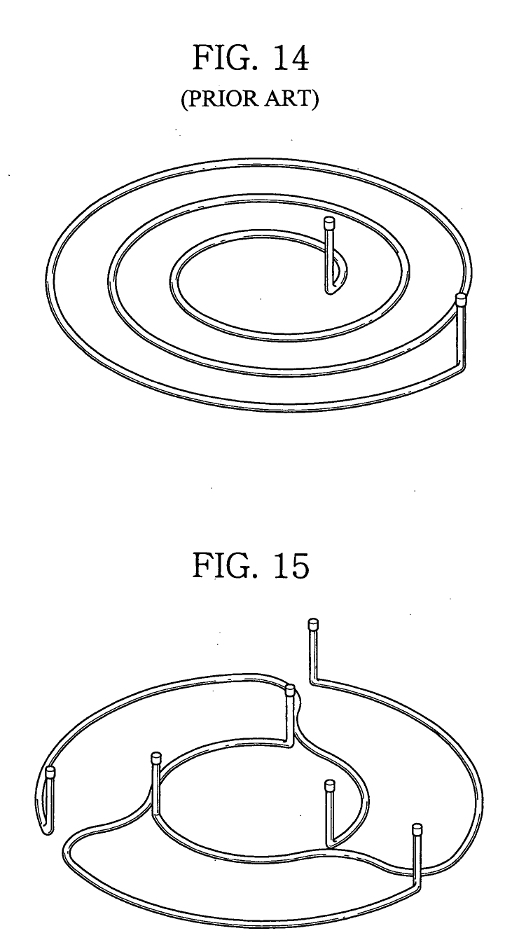

FIG. 14 is a perspective view of a conventional antenna. FIG. 15 is a perspective view of the antenna shown in FIG. 1.

The inner terminals of the antennas shown in FIGS. 14 and 15 were used as input terminals for impressing a voltage across the antennas, and the outer terminals of the antennas were used for grounding the antennas. The centers of the antennas were located at a point Co. RF currents of about 5 amperes and at a frequency of about 13.56 MHz were supplied to the inner terminals of each of the antennas. Radial components Br (A/m) of magnetic fields were measured in a plane parallel to and spaced from the antennas by about 5 cm.

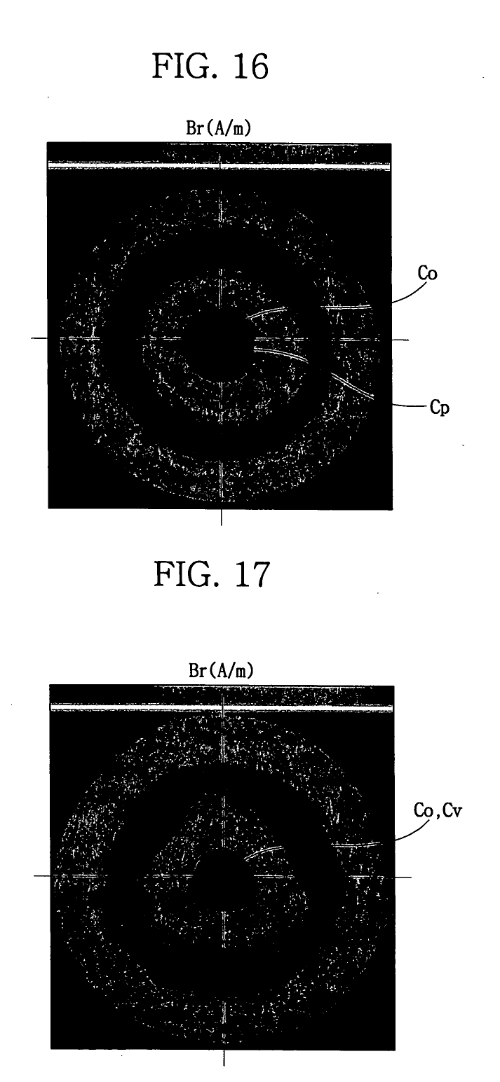

FIG. 16 shows the magnetic field that was generated by the current flow through the conventional antenna shown in FIG. 14. FIG. 17 shows the magnetic field that was generated by the current flow through the antenna shown in FIG. 15.

As is clear from FIG. 16, the center Cp of the magnetic field is offset from the center Co of the conventional antenna (in the direction toward the right lower portion of the figure). On the other hand, as is shown in FIG. 17, the center Cv of the magnetic field coincided with the center Co of the antenna according to the present invention. It should be noted that the center Cp of the magnetic field generated from the antenna of FIG. 14 was shifted from the center of the antenna toward the outer terminal used for grounding the antenna. As a result, plasma produced using the antenna shown in FIG. 14 might have a density that varies along a direction corresponding to the direction from the center of the antenna towards the outer terminal, i.e., the plasma might not be uniformly distributed in the chamber. To the contrary, the center Cv of the magnetic field generated from the antenna shown in FIG. 15 was located at the center Co of the antenna. Thus, plasma produced using the antenna in FIG. 15 can be uniformly distributed in the chamber.

Measurements of Electric Fields that are Generated by a Conventional Antenna and an Antenna According to the Present Invention

Under the same conditions described above, azimuthal components E_{θ} (V/m) of electric fields generated by the antennas shown in FIGS. 14 and 15 were measured in a plane spaced from the antennas by about 5 cm.

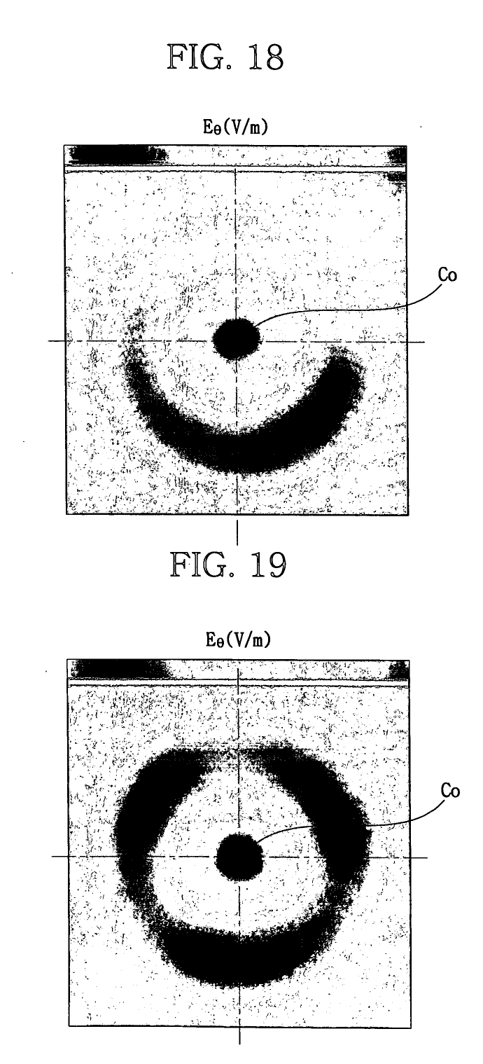

FIG. 18 shows the electric field that was generated by the antenna of FIG. 14. FIG. 19 shows the electric field that was generated by the antenna of FIG. 15.

As is clear from FIG. 18, the electric field emanating from the antenna of FIG. 14 was not uniform about the center Co of the antenna. On the other hand, as shown in FIG. 19, the electric field emanating from the antenna in FIG. 15 formed concentric circles around the center Co of the antenna. Accordingly, the conventional antenna might not be able to be used to produce a uniform plasma within a plasma processing chamber. However, the antenna of the present invention readily facilitates the forming of uniform plasma within such a chamber.

According to the present invention, an antenna of a plasma processing apparatus comprises discrete branches having substantially identical shapes, and which are disposed symmetrically and form concentric patterns. Thus, a uniform may be produced using the antenna according to the present invention. Also, the branches are electrically connected in parallel so that the impedance of the antenna is relatively low, whereby the antenna transmits RF power with a high degree of efficiency.

Although the present invention has been described above in connection with the preferred embodiments thereof, it is noted that modifications and variations of the preferred embodiments will become readily apparent to those skilled in the art in light of the above teachings. It is therefore to be understood that the disclosed embodiments of the present invention may be modified or altered within the true spirit and scope of the invention as defined by the appended claims.

1. An antenna for use in producing plasma comprising:
a plurality of discrete branches having substantially identical shapes, the branches being symmetrically disposed about a central axis, and the discrete branches comprising pattern-forming portions which lie completely in at least two concentric geometric figures whose centers coincide with the central axis.

2. The antenna of claim 1, wherein the concentric geometric figures are concentric circles.

3. The antenna of claim 2, wherein each of the branches comprises a plurality of arcuate pattern-forming portions, and at least one connecting portion extending between and connecting the pattern-forming portions, the pattern-forming portions constituting each of the branches extending along the concentric circles, respectively, whereby the pattern-forming portions constituting each of said branches have different radii of curvature.

4. The antenna of claim 3, wherein the pattern-forming portions all lie in substantially the same plane.

5. The antenna of claim 3, wherein the pattern-forming portions constituting each of the branches are disposed in parallel planes, respectively.

6. The antenna of claim 3, wherein the radial spacing between the center and the radially innermost one of the concentric circles, and the radial spacing between each adjacent pair of the concentric circles are substantially identical.

7. The antenna of claim 3, wherein each of the pattern-forming portions has a length between that of about a semi-circle and about a quarter of a circle.

8. The antenna of claim 1, further comprising electrical terminals at ends of each of the branches.

9. A plasma processing apparatus comprising:
a processing chamber into which a reaction gas is introduced;
a chuck on which a wafer is to be supported disposed at a lower portion of the chamber; and
an antenna disposed over said chamber, the antenna including a plurality of discrete branches having substantially identical shapes, the branches being symmetrically disposed about a central point, and the discrete branches comprising pattern-forming portions which lie completely in at least two concentric geometric figures whose centers coincide with the central point.

10. The apparatus of claim 9, wherein the concentric figures are concentric circles, and each of the branches of the antenna comprises a plurality of arcuate pattern-forming portions, and at least one connecting portion extending between and connecting the pattern-forming portions, the pattern-forming portions constituting each of the branches extending along the concentric circles, respectively, whereby the pattern-forming portions constituting each of the branches have different radii of curvature.

11. The apparatus of claim 10, wherein the chamber comprises a substantially flat circular upper wall, and the pattern-forming portions all lie in substantially the same plane.

12. The apparatus of claim 10, wherein the chamber comprises a dome-shaped upper wall, and the pattern-forming portions constituting each of the branches are disposed in parallel planes, respectively, spaced along the height of the dome-shaped upper wall.
